(19) United States
(12) Patent Application Publication
(10) Pub. No.: US 2019/0081238 A1
(43) Pub. Date: Mar. 14, 2019

(54) METHOD OF MANUFACTURING SEMICONDUCTOR DEVICE

(71) Applicant: KOKUSAI ELECTRIC CORPORATION, Tokyo (JP)

(72) Inventor: Masahito KITAMURA, Toyama-shi (JP)

(73) Assignee: KOKUSAI ELECTRIC CORPORATION, Tokyo (JP)

(21) Appl. No.: 16/126,677

(22) Filed: Sep. 10, 2018

(30) Foreign Application Priority Data
Sep. 11, 2017 (JP) 2017-174090

(51) Int. Cl. H01L 45/00; B24B 37/04; B24B 37/015

(52) U.S. Cl. CPC H01L 45/1675; B24B 37/042; H01L 21/30625; H01L 45/06; H01L 45/1683; B24B 37/015

(57) ABSTRACT

Described herein is a technique capable of improving a quality of a phase change film formed on a substrate. According to the technique described herein, there is provided a method of manufacturing a semiconductor device, including: (a) supplying a reducing first gas onto a substrate while heating the substrate, wherein the substrate includes a first metal-containing film and an insulating film with recesses and the first metal-containing film is exposed at the recesses; and (b) supplying a second gas, a third gas and a fourth gas into the recesses to form a phase change film in the recesses after (a) is performed.

### CROSS-REFERENCE TO RELATED PATENT APPLICATION

This non-provisional U.S. patent application claims priority under 35 U.S.C. § 119 of Japanese Patent Application No. 2017-174090, filed on Sep. 17, 2017, in the Japanese Patent Office, the entire contents of which are hereby incorporated by reference.

### BACKGROUND

### 1. Field

The present disclosure relates to a method of manufacturing a semiconductor device.

### 2. Description of the Related Art

A film-forming process for forming a phase change film, which is one of manufacturing processes of a semiconductor device, is performed on a substrate.

It is required to improve a quality of the phase change film formed on the substrate.

### SUMMARY

Described herein is a technique capable of improving the quality of the phase change film formed on the substrate.

According to one aspect of the technique described herein, there is provided a method of manufacturing a semiconductor device including: (a) supplying a reducing first gas onto a substrate while heating the substrate, wherein the substrate includes a first metal-containing film and an insulating film with recesses and the first metal-containing film is exposed at the recesses; and (b) supplying a second gas, a third gas and a fourth gas into the recesses to form a phase change film in the recesses after (a) is performed

### BRIEF DESCRIPTION OF THE DRAWINGS

FIG. 1 schematically illustrates a substrate processing apparatus according to an embodiment described herein.

FIG. 2 schematically illustrates a gas supply system of the substrate processing apparatus according to the embodiment.

FIG. 3 is a block diagram schematically illustrating a configuration of a controller and components controlled by the controller of the substrate processing apparatus according to the embodiment.

FIG. 4 is a flowchart illustrating a substrate processing according to the embodiment.

FIGS. 5A through 5D schematically illustrate cross-sectional views of a substrate according to the embodiment.

FIGS. 6A through 6C schematically illustrate cross-sectional views of the substrate according to the embodiment.

FIGS. 7A through 7D schematically illustrate cross-sectional views of the substrate when a third processing step is performed according to the embodiment.

FIG. 8 is a flowchart illustrating a first processing step according to the embodiment.

FIG. 9 is a flowchart illustrating a second processing step according to the embodiment.

FIG. 10 is a flowchart illustrating a first modified example of the second processing step according to the embodiment.

FIG. 11 is a flowchart illustrating a second modified example of the second processing step according to the embodiment.

FIG. 12 is a flowchart illustrating a fourth processing step according to the embodiment.

FIGS. 13A and 13B illustrate exemplary gas supply sequences of the fourth processing step according to the embodiment.

FIG. 14 is a flowchart illustrating the third processing step according to the embodiment.

FIG. 15 schematically illustrates a substrate processing system according to the embodiment.

FIG. 16 schematically illustrates a polishing apparatus according to the embodiment.

### DETAILED DESCRIPTION

Embodiments will be described below.

### Embodiment

Hereafter, an embodiment will be described with reference to the drawings.

(1) Configuration of Substrate Processing Apparatus

First, a substrate processing apparatus according to the embodiment will be described.

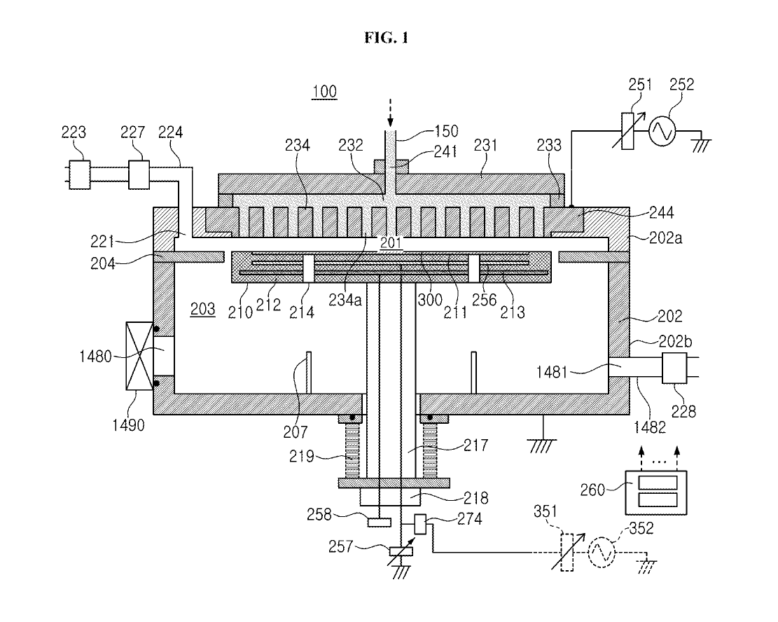

The substrate processing apparatus 100 according to the embodiment will be described. As shown in FIG. 1, the substrate processing apparatus 100 includes, for example, a single wafer type substrate processing apparatus.

As shown in FIG. 1, the substrate processing apparatus 100 includes a process vessel 202. For example, the process vessel 202 is a flat and sealed vessel having a circular horizontal cross-section. The process vessel 202 is made of a metal material such as aluminum (Al) and stainless steel (SUS) or quartz. A process space (a process chamber) 201 where a substrate 300 such as a silicon wafer is processed and a transfer space (transfer chamber) 203 are provided in the process vessel 202. The process vessel 202 is constituted by an upper vessel 202a and a lower vessel 202b. A partition plate (partition part) 204 is provided between the upper vessel 202a and the lower vessel 202b. The process chamber 201 is defined by at least the upper vessel 202a and a substrate placing surface 211 which is described later. The transfer chamber 203 is defined by at least the lower vessel 202b and a lower surface of a substrate support 212 which is described later.

A substrate loading/unloading port 1480 is provided on a side surface of the lower vessel 202b adjacent to a gate valve 1490. The substrate 300 is moved between a vacuum transfer chamber (not shown) and the transfer chamber 203 through the substrate loading/unloading port 1480. Lift pins 207 are provided at the bottom of the lower vessel 202b. The lower vessel 202b is electrically grounded.

A substrate support part 210 is provided in the process chamber 201 to support the substrate 300. The substrate support part 210 includes the substrate support 212 having the substrate placing surface 211 on which the substrate 300 is placed and a heater 213 serving as a heating mechanism. Holes 214 wherethrough the lift pins 207 penetrate are provided in the substrate support 212 at positions corresponding to the lift pins 207. The heater 213 is electrically connected to a temperature controller 258. The temperature controller 258 is configured to control the temperature of the heater 213. A second electrode 256 for applying a bias to the substrate 300 or the process chamber 201 may be provided in the substrate support 212. The second electrode 256 is electrically connected to a bias controller 257. The bias controller 257 is configured to adjust the bias. A second high frequency power source 352 and a second matching mechanism 351 may be connected to the second electrode 256.

The substrate support 212 is supported by a shaft 217. The shaft 217 penetrates the bottom of the process vessel 202 and is connected to an elevating mechanism 218 at the outside of the process vessel 202. The substrate 300 placed on the substrate placing surface 211 of the substrate support 212 may be elevated and lowered by operating the elevating mechanism 218 by elevating and lowering the shaft 217 and the substrate support 212. A bellows 219 covers a lower end portion of the shaft 217 to maintain the process chamber 201 airtight.

When the substrate 300 is transported, the substrate support 212 is lowered until a wafer transfer position is reached. When the substrate 300 is processed, the substrate support 212 is elevated until a processing position (wafer processing position) shown FIG. 1 is reached. When the substrate support 212 is at the wafer transfer position, upper ends of the lift pins 207 protrude from the substrate placing surface 211.

Specifically, when the substrate support 212 is lowered to the wafer transfer position, the upper ends of the lift pins 207 protrude from the upper surface of the substrate placing surface 211, and the lift pins 207 support the substrate 300 from thereunder. When the substrate support 212 is elevated to the wafer processing position, the lift pins 207 are retracted from the upper surface of the substrate placing surface 211 and the substrate placing surface 211 supports the substrate 300 from thereunder. Preferably, the lift pins 207 are made of a material such as quartz and alumina since the lift pins 207 are in direct contact with the substrate 300.

<Exhaust System>

A first exhaust port 221, which is a part of a first exhaust system for exhausting an inner atmosphere of the process chamber 201, is connected to an inner surface of the process chamber 201 (the upper vessel 202a). An exhaust pipe 224 is connected to the first exhaust port 221. A pressure controller 227 such as an APC (Automatic Pressure Controller) for adjusting the inner pressure of the process chamber 201 to a predetermined pressure and a vacuum pump 223 are connected to the exhaust pipe 224 in order. The first exhaust port 221, the exhaust pipe 224 and the pressure controller 227 constitute the first exhaust system (first exhaust line). The first exhaust system may further include the vacuum pump 223. A second exhaust port 1481 for exhausting an inner atmosphere of the transfer chamber 203 is connected to the surface of an inner wall of the transfer chamber 203. An exhaust pipe 1482 is connected to the second exhaust port 1481. A pressure controller 228 is connected to the exhaust pipe 1482. The inner atmosphere of the transfer chamber 203 may be exhausted through the exhaust pipe 1482 by the pressure controller 228 until a predetermined pressure is reached. The inner atmosphere of the process chamber 201 may also be exhausted through the transfer chamber 203. The second exhaust port 1481, the exhaust pipe 1482 and the pressure controller 228 constitute a second exhaust system (second exhaust line). The exhaust system is constituted by the first exhaust system and the second exhaust system.

<Gas Introduction Port>

A shower head 234 is provided at the upper portion of the process chamber 201. A gas introduction port 241 for supplying various gases into the process chamber 201 is provided at an upper surface (ceiling) of the shower head 234. A detailed configuration of each gas supply system connected to the gas introduction port 241 will be described later.

<Gas Dispersion Mechanism)

The shower head 234 serving as a gas dispersion mechanism includes a buffer chamber 232 and a first electrode 244 which is a part of an activation mechanism described later. Holes 234a for dispersing and supplying a gas to the substrate 300 are provided at the first electrode 244. The shower head 234 is provided between the gas introduction port 241 and the process chamber 201. A gas supplied through the gas introduction port 241 is supplied to the buffer chamber 232 of the shower head 234 and is then supplied to the process chamber 201 via the holes 234a. The buffer chamber 232 is also referred to as a “dispersion part”.

The first electrode 244 is made of a conductive metal. The first electrode 244 is a part of a first activation mechanism (also referred to as a “first excitation mechanism” or “first plasma generator”) for exciting the gas. An electromagnetic wave (high frequency power or microwave) can be applied to the first electrode 244. When a cover 231 is made of a conductive material, an insulating block 233 is provided between the cover 231 and the first electrode 244. The insulating block 233 electrically insulates the cover 231 from the first electrode 244.

<First Activation Mechanism (First Plasma Generator)>

A first matching mechanism 251 and a first high frequency power supply 252, which are a part of the first activation mechanism, are connected to the first electrode 244. The first matching mechanism 251 and the first high frequency power supply 252 are configured to supply an electromagnetic wave (high frequency power or microwave) to the first electrode 244. When the electromagnetic wave is supplied to the first electrode 244, the gas supplied into the process chamber 201 is activated. The first electrode 244 is capable of generating capacitively coupled plasma. Specifically, the first electrode 244 is a conductive plate supported by the upper vessel 202a. The first activation mechanism is constituted by at least the first electrode 244, the first matching mechanism 251 and the first high frequency power supply 252.

<Second Activation Mechanism (Second Plasma Generator)>

A second matching mechanism 351 and a second high frequency power supply 352, which are a part of a second activation mechanism (also referred to as a “second excitation mechanism” or “second plasma generator”), are connected to the second electrode 256 via a switch 274. The second matching mechanism 351 and the second high frequency power supply 352 are configured to supply an electromagnetic wave (high frequency power or microwave) to the second electrode 256. A frequency of the electromagnetic wave supplied from the second high frequency power supply 352 is different from a frequency of the electromagnetic wave supplied from the first high frequency power supply 252. Specifically, the frequency of the electromagnetic wave supplied from the second high frequency power supply 352 is lower than the frequency of the electromagnetic wave supplied from the first high frequency power supply 252. When the electromagnetic wave is supplied to the second electrode 256, the gas supplied into the process chamber 201 is activated. The second matching mechanism 351 and the second high frequency power supply 352 may be provided without providing the switch 274 such that the electromagnetic wave can be supplied directly from the second high frequency power supply 352 to the second electrode 256.

<Gas Supply System>

A gas supply pipe 150 is connected to the gas introduction port 241. Various gases, for example, at least one of the a first gas, a second gas, a third gas, a fourth gas, a fifth gas, a sixth gas, a seventh gas and an eighth gas described later can be supplied into the shower head 234 through the gas supply pipe 150 and the gas introduction port 241.

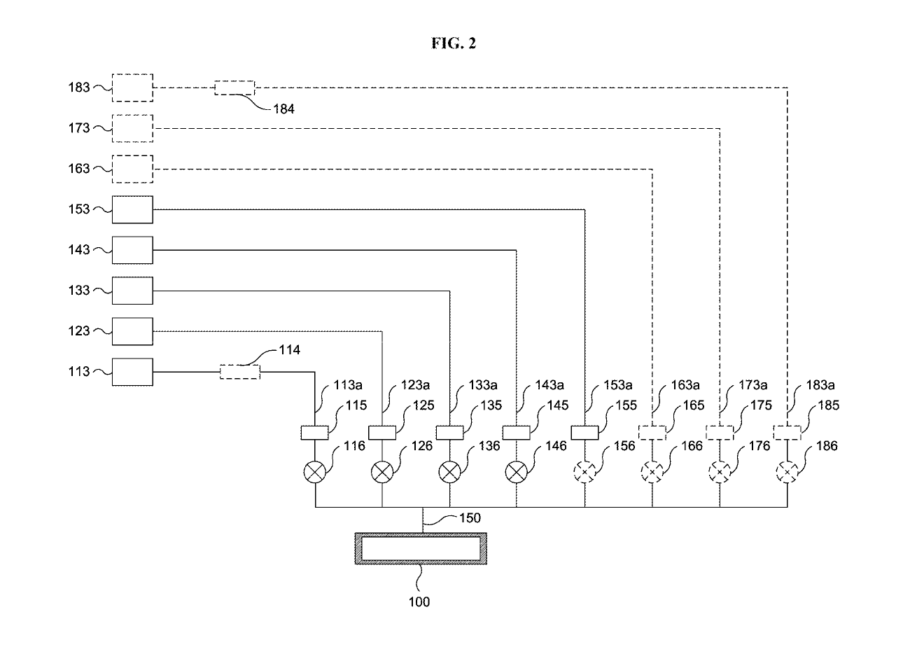

FIG. 2 schematically illustrates a gas supply system including gas supply mechanisms such as a first gas supply mechanism, a second gas supply mechanism, a third gas supply mechanism, a fourth gas supply mechanism, a fifth gas supply mechanism, a sixth gas supply mechanism, a seventh gas supply mechanism and an eighth gas supply mechanism.

As shown in FIG. 2, gas supply pipes are connected to the gas supply pipe 150. Specifically, a first gas supply pipe 113a, a second gas supply pipe 123a, a third gas supply pipe 133a, a fourth gas supply pipe 143a, a fifth gas supply pipe 153a, a sixth gas supply pipe 163a, a gas supply pipe 173a and an eighth gas supply pipe 183a are connected to the gas supply pipe 150.

<First Gas Supply Mechanism>

The first gas supply mechanism is constituted by the first gas supply pipe 113a, a mass flow controller (MFC) 115 and a valve 116. The first gas supply mechanism may further include a first gas supply source 113 connected to the first gas supply pipe 113a. A reducing gas serving as the first gas is supplied from the first gas supply source 113. The reducing gas is a gas that reduces oxygen (O). For example, the reducing gas may be a hydrogen (H)-containing gas. Specifically, hydrogen (H₂) gas is used as the reducing gas. Preferably, the hydrogen-containing gas of the embodiment is a gas that does not contain an oxygen (O) element. The hydrogen-containing gas may be a forming gas containing hydrogen (H) and nitrogen (N). A remote plasma unit (RPU) 114 serving as a remote plasma mechanism may be provided at the first gas supply pipe 113a to activate the first gas.

<Second Gas Supply Mechanism>

The second gas supply mechanism is constituted by the second gas supply pipe 123a, a mass flow controller (MFC) 125 and a valve 126. The second gas supply mechanism may further include a second gas supply source 123 connected to the second gas supply pipe 123a. A gas containing a group 14 element (group IVA) and serving as the second gas is supplied from the second gas supply source 123. Specifically, a gas containing germanium (Ge) is supplied from the second gas supply source 123. For example, a gas such as isobutylgermane (IBGe) gas, tetrakis (dimethylamino) germanium (TDMAGe) gas, dimethylamino germanium trichloride (DMAGeC), GeH₄, GeCl₂, GeF₂ and GeBr₂ and mixtures thereof may be used as the gas containing germanium (Ge).

<Third Gas Supply Mechanism>

The third gas supply mechanism is constituted by the third gas supply pipe 133a, a mass flow controller (MFC) 135 and a valve 136. The third gas supply mechanism may further include a third gas supply source 133 connected to the third gas supply pipe 133a. A gas containing a group 15 element (group VA) and serving as the third gas is supplied from the third gas supply source 133. Specifically, a gas containing antimony (Sb) is supplied from the third gas supply source 133. For example, a gas such as tris (dimethylamino) antimony (TDMASb), triisopropyl antimony (TIPSb) gas, triethyl antimony (TESb) gas and tert butyl dimethyl antimony (TBDMSb) gas and mixtures thereof may be used as the gas containing antimony (Sb).

<Fourth Gas Supply Mechanism>

The fourth gas supply mechanism is constituted by the fourth gas supply pipe 143a, a mass flow controller (MFC) 145 and a valve 146. The fourth gas supply mechanism may further include a fourth gas supply source 143 connected to the fourth gas supply pipe 143a. A gas containing a group 16 element (group VIA) and serving as the fourth gas is supplied from the fourth gas supply source 143. Specifically, a gas containing tellurium (Te) is supplied from the fourth gas supply source 143. For example, a gas such as diisopropyl tellurium (diisopropyl telluride, DIPTe), dimethyl tellurium (dimethyl telluride, DMTe), diethyl tellurium (diethyl telluride, DETe) and ditert butyl tellurium (DtBTe) and mixtures thereof may be used as the gas containing tellurium (Te).

<Fifth Gas Supply Mechanism>

The fifth gas supply mechanism is constituted by the fifth gas supply pipe 153a, a mass flow controller (MFC) 155 and a valve 156. The fifth gas supply mechanism may further include a fifth gas supply source 153 connected to the fifth gas supply pipe 153a. An inert gas serving as the fifth gas is supplied from the fifth gas supply source 153. Specifically, at least one of nitrogen (Nz) gas, argon (Ar) gas, helium (He) gas, neon (Ne) gas and xenon (Xe) gas may be used as the inert gas.

<Sixth Gas Supply Mechanism>

The sixth gas supply mechanism is constituted by the sixth gas supply pipe 163a, a mass flow controller (MFC) 165 and a valve 166. The sixth gas supply mechanism may further include a sixth gas supply source 163 connected to the sixth gas supply pipe 163a. A titanium (Ti)-containing gas serving as the sixth gas is supplied from the sixth gas supply source 163. For example, titanium tetrachloride (TiCl₄) gas is supplied from the sixth gas supply source 163 as the titanium-containing gas.

<Seventh Gas Supply Mechanism>

The seventh gas supply mechanism is constituted by the seventh gas supply pipe 173a, a mass flow controller (MFC) 175 and a valve 176. The seventh gas supply mechanism may further include a seventh gas supply source 173 connected to the seventh gas supply pipe 173a. A silicon (Si)-containing gas serving as the seventh gas is supplied from the seventh gas supply source 173. For example, monosilane (SiH₄) gas is supplied from the seventh gas supply source 173 as the silicon-containing gas.

<Eighth Gas Supply Mechanism>

The eighth gas supply mechanism is constituted by the eighth gas supply pipe 183a, a mass flow controller (MFC) 185 and a valve 186. The eighth gas supply mechanism may further include an eighth gas supply source 183 connected to the eighth gas supply pipe 183a. A nitrogen (N)-containing gas serving as the eighth gas is supplied from the eighth gas supply source 183. For example, ammonia (NH₃) gas is supplied from the eighth gas supply source 183 as the nitrogen-containing gas. A remote plasma unit (RPU) 184 serving as a remote plasma mechanism may be provided at the eighth gas supply pipe 183a to activate the eighth gas.

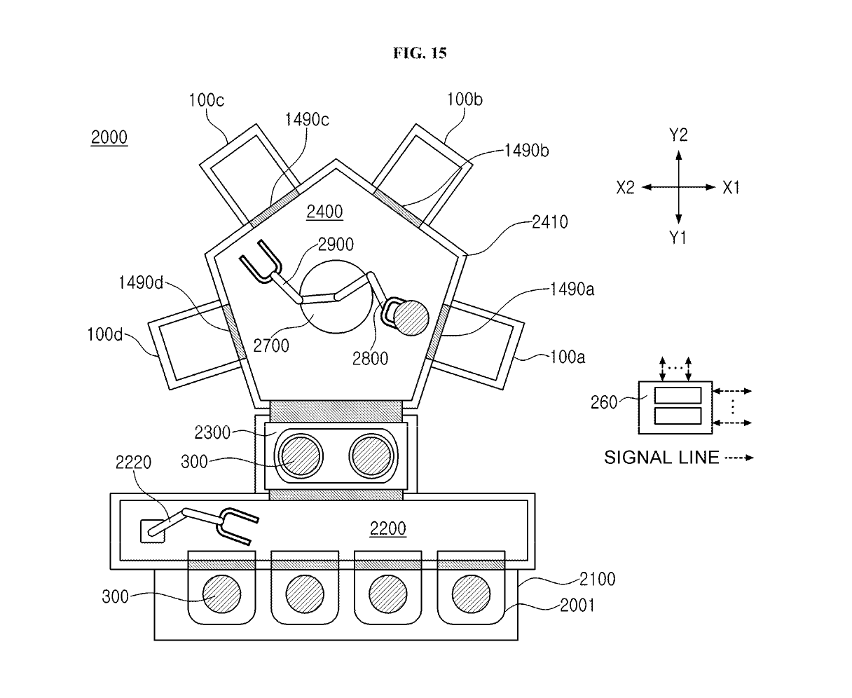

Hereinafter, a substrate processing system 2000 according to the embodiment will be described with reference to FIG. 15. A substrate processing according to the embodiment includes a first processing step S101, a second processing step S201 and a third processing step S301 as described later. The first processing step S101, the second processing step S201 and the third processing step S301 may be performed by the same substrate processing apparatus 100 described above. However, in order to prevent contamination due to the gases used in each processing step and to shorten the time for adjusting the temperature of the substrate when the processing temperatures are different in each processing step, it is preferable that the first processing step S101, the second processing step S201 and the third processing step S301 are performed by different substrate processing apparatuses. For example, the first processing step S101, the second processing step S201 and the third processing step S301 are performed by substrate processing apparatuses of the substrate processing system 2000 shown in FIG. 15. The substrate processing system 2000 is configured to process the substrate 300. The substrate processing system 2000 includes, for example, an I/O stage 2100, an atmospheric transfer chamber 2200, a load lock chamber 2300, a vacuum transfer chamber 2400 and substrate processing apparatuses 100a, 100b, 100c and 100d. Next, each component of the substrate processing system 2000 will be described in detail. In the following description of the substrate processing system 2000, front, rear, left and right directions are based on FIG. 15. Hereinafter, front, rear, left and right directions are indicated by arrow Y₁, arrow Y₂, arrow X₂ and arrow X₁ shown in FIG. 15, respectively. Since the configuration of the substrate processing apparatuses 100a, 100b, 100c and 100d are substantially the same as that of the substrate processing apparatus 100 described above, the description thereof is omitted.

<Atmospheric Transfer Chamber and I/O Stage>

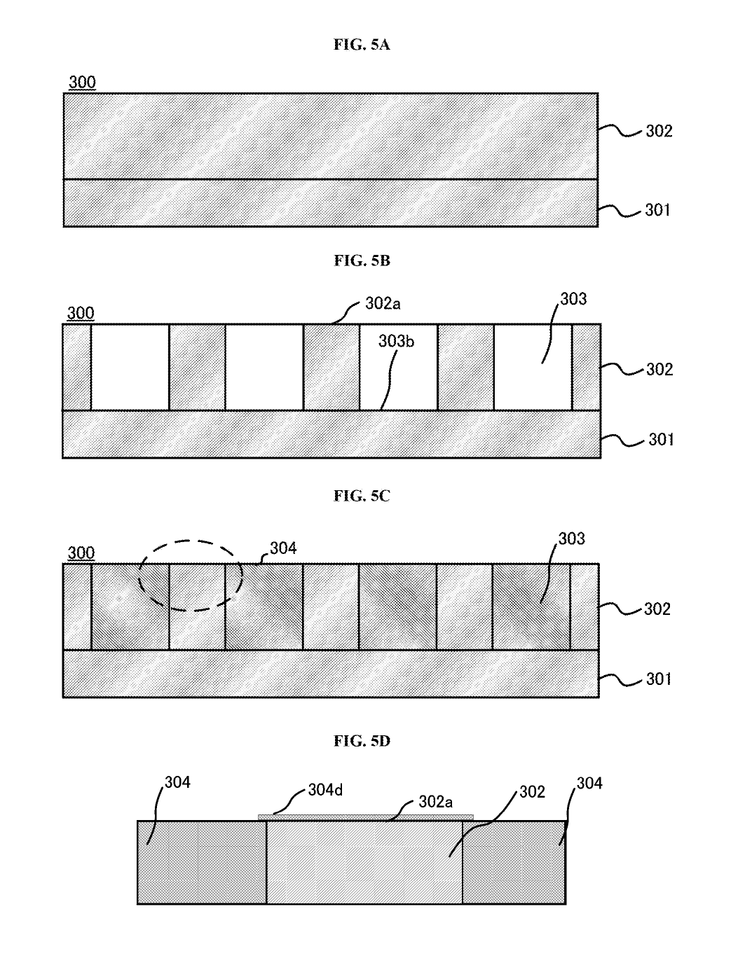

The I/O stage (loading port shelf) 2100 is provided at a front side of the substrate processing system 2000. A plurality of pods 2001 is placed on the I/O stage 2100. The pod 2011 is used as a carrier for transferring the substrate 300. Unprocessed substrate 300 or processed substrate 300 is horizontally accommodated in multiple stages in each pod 2001. In the embodiment, the unprocessed substrate 300 refers to the substrate 300 shown in FIGS. 5B, 6B and 7B.

The pod 2001 is loaded onto the I/O stage 2100 and unloaded from the I/O stage 2100 by a transfer robot (not shown).

The I/O stage 2100 is provided adjacent to the atmospheric transfer chamber 2200. The load lock chamber 2300, which will be described later, is connected to a side of the atmospheric transfer chamber 2200 other than the side to which the I/O stage 2100 is provided.

An atmospheric transfer robot 2220 configured to transfer the substrate 300 is provided in the atmospheric transfer chamber 120. The atmospheric transfer robot 2220 serves as a first transfer robot.

<Load Lock Chamber>

The load lock chamber 2300 is provided adjacent to the atmospheric transfer chamber 2200. Since an inner pressure of the load lock chamber 2300 is adjusted to be equal to an inner pressure of the atmospheric transfer chamber 2200 or an inner pressure of the vacuum transfer chamber 2400, the structure of the load lock chamber 2300 is capable of withstanding a negative pressure.

<Vacuum Transfer Chamber>

The substrate processing system 2000 includes a transfer space, i.e., the vacuum transfer chamber (transfer module: TM) 2400, in which the substrate 300 is transported under the negative pressure. A housing 2410 constituting the vacuum transfer chamber 2400 is pentagonal when viewed from above. The load lock chamber 2300 and the substrate processing apparatuses 100a, 100b, 100c and 100d where the substrate 300 is processed are connected to respective sides of the pentagonal housing 2410. A vacuum transfer robot 2700 for transferring the substrate 300 under the negative pressure is provided at approximately the center of the vacuum transfer chamber 2400. The vacuum transfer robot 2700 serves as a second transfer robot. In the embodiment, the shape of the vacuum transfer chamber 2400 is exemplified as pentagonal. However, the shape of the vacuum transfer chamber 2400 is not limited thereto. For example, the vacuum transfer chamber 2400 may have a polygonal shape such as a quadrilateral shape and a hexagonal shape.

The vacuum transfer robot 2700 provided in the vacuum transfer chamber 2400 includes two arms 2800 and 2900 that can be independently operated. The vacuum transfer robot 2700 is controlled by a controller 260 described later.

As shown in FIG. 15, gate valves (GVs) 1490a, 1490b, 1490c and 1490d are provided to correspond to the substrate processing apparatuses 100a, 100b, 100c and 100d. Specifically, the gate valve 1490a is provided at the substrate processing apparatus 100a between the substrate processing apparatus 100a and the vacuum transfer chamber 2400, the gate valve 1490b is provided at the substrate processing apparatus 100b between the substrate processing apparatus 100b and the vacuum transfer chamber 2400, the gate valve 1490c is provided at the substrate processing apparatus 100c between the substrate processing apparatus 100c and the vacuum transfer chamber 2400, and the gate valve 1490d is provided at the substrate processing apparatus 100d between the substrate processing apparatus 100d and the vacuum transfer chamber 2400.

Each of the substrate processing apparatuses 100a, 100b, 100c and 100d is provided with the substrate loading/unloading port 1480 described above. By opening/closing the substrate loading/unloading port 1480 of the substrate processing apparatuses 100a, 100b, 100c and 100d by each of the gate valves 1490a, 1490b, 1490c and 1490d, respectively, the substrate 300 can be transferred between the vacuum transfer chamber 2400 and each of the substrate processing apparatuses 100a, 100b, 100c and 100d via the substrate loading/unloading port 1480 of the substrate processing apparatuses 100a, 100b, 100c and 100d, respectively.

In the following description, an exemplary substrate processing sequence of the substrate processing will be described. In the exemplary substrate processing sequence, the first processing step S101 is performed by the substrate processing apparatus 100a, the second processing step S201 is performed by the substrate processing apparatus 100b and the third processing step S301 is performed by the substrate processing apparatus 100c. The first gas supply mechanism and the fifth gas supply mechanism described above are connected to the gas supply pipe 150 of the substrate processing apparatus 100a. The second gas supply mechanism, the third gas supply mechanism, the fourth gas supply mechanism and the fifth gas supply mechanism described above are connected to the gas supply pipe 150 of the substrate processing apparatus 100b. The fifth gas supply mechanism, the sixth gas supply mechanism and the eighth gas supply mechanism described above are connected to the gas supply pipe 150 of the substrate processing apparatus 100c. The seventh gas supply mechanism described above may be connected to the gas supply pipe 150 of the substrate processing apparatus 100c.

The substrate processing apparatus 100d shown in FIG. 15 may be configured to perform the second processing step S201 when it is the second processing step S201 that takes the longest time among the first processing step S101, the second processing step S201 and the third processing step S301. The substrate processing apparatus 100d shown in FIG. 15 may not be used in the exemplary substrate processing sequence or may not be provided in the substrate processing system 2000. The substrate processing system 2000 shown in FIG. 15 includes four substrate processing apparatuses, that is, the substrate processing apparatuses 100a, 100b, 100c and 100d. However, in the embodiment, the number of substrate processing apparatuses included in the substrate processing system 2000 is not limited thereto.

<Controller>

As shown in FIG. 1, the substrate processing apparatus 100 includes the controller 260 configured to control the operation of components of the substrate processing apparatus 100.

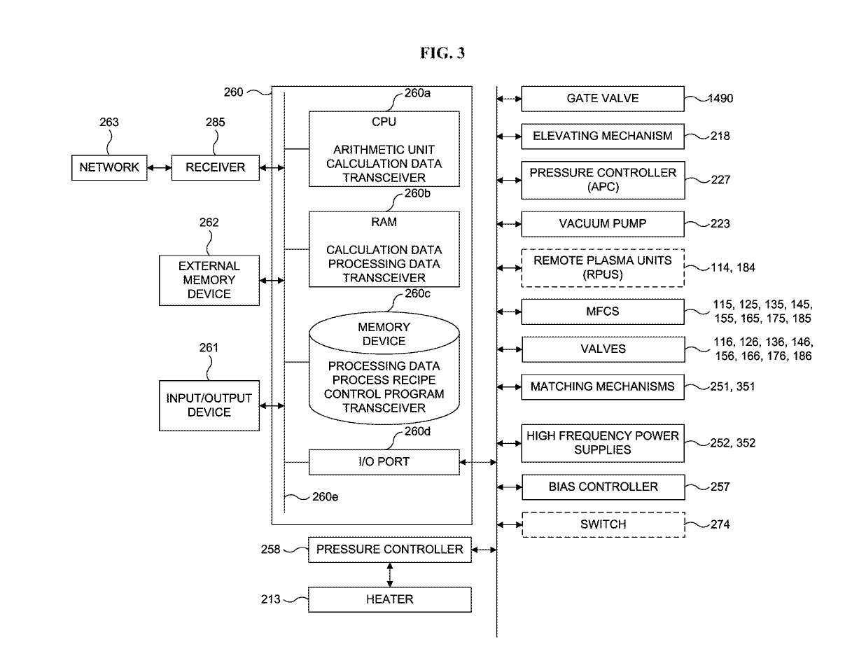

FIG. 3 is a block diagram schematically illustrating a configuration of the controller 260 and components connected to the controller 260 or controlled by the controller 260. The controller 260, which is a control device (control mechanism), may be embodied by a computer having a CPU (Central Processing Unit) 260a, a RAM (Random Access Memory) 260b, a memory device 260c and an I/O port 26d0. The RAM 260b, the memory device 260c and the I/O port 260d may exchange data with the CPU 260a via an internal bus 260e. An input/output device 261 such as a touch panel, an external memory device 262 and a receiver 285 may be additionally connected to the controller 260.

The memory device 260c may be embodied by components such as a flash memory and a HDD (Hard Disk Drive). For example, a control program for controlling the operation of the substrate processing apparatus 100; a process recipe in which information such as the sequence and the condition of the substrate processing described later is stored; and calculation data and processing data generated in the process of setting the process recipe used for processing the substrate 300 are readably stored in the memory device 260c. The process recipe is a program that is executed by the controller 260 to obtain a predetermined result by performing sequences of the substrate processing. Hereinafter, the process recipe and the control program may be collectively referred to simply as “program.” In the present specification, the term “program” may refer to only the process recipe, only the control program, or both. The RAM 260b is a work area in which the program or the data such as the calculation data and the processing data read by the CPU 260a are temporarily stored.

The I/O port 260d is electrically connected to the components such as the gate valve 1490, the elevating mechanism 218, the temperature controller 258, the pressure controller 227, the vacuum pump 223, the first matching mechanism 251, the second matching mechanism 351, the first high frequency power supply 252, the second high frequency power supply 352, the mass flow controllers (MFCs) 115, 125, 135, 145, 155, 165, 175 and 185, the valves 116, 126, 136, 146, 156, 166, 176 and 186, the remote plasma units (RPUs) 114 and 184 and the bias controller 257. The I/O port 264 may be electrically connected to the switch 274.

The CPU 260a, which is an arithmetic unit, is configured to read and execute the control program stored in the memory device 260c, and read the process recipe stored in the memory device 260c in accordance with an instruction such as an operation command inputted via the input/output device 261. The CPU 260a is capable of computing the calculation data by comparing a value inputted from the receiver 285 with the process recipe or control data stored in the memory device 260c. The CPU 260a may select the process recipe based on the calculation data. The CPU 260a may be configured to control operation of the substrate processing apparatus 100 according to the process recipe. For example, the CPU 260a may be configured to perform operations, according to the process recipe, such as an opening/closing operation of the gate valve 1490, an elevating/lowering operation of the elevating mechanism 218, an operation of supplying electrical power to the heater 213 via the temperature controller 258, a pressure adjusting operation of the pressure controller 227, an ON/OFF control of the vacuum pump 223, gas flow rate adjusting operations of the MFCs 115, 125, 135, 145, 155, 165, 175 and 185, gas activation operations of the RPUs 114 and 184, opening/closing operations of the valves 116, 126, 136, 146, 156, 166, 176 and 186, matching operations of the power by the matching mechanisms 251 and 351, control operations of the power by the high frequency power supplies 252 and 352, a control operation of the bias controller 257 and an ON/OFF operation of the switch 274. A transceiver of the CPU 260a may transmit or receive control data according to the process recipe to or from the components described above to control the operations of the components.

The controller 260 is not limited to a dedicated computer. The controller 260 may be embodied by a general-purpose computer. The controller 260 according to the embodiment may be embodied by preparing the external memory device 262 (e.g., a magnetic tape, a magnetic disk such as a flexible disk and a hard disk, an optical disk such as a CD and a DVD, a magneto-optical disk such as an MO, a semiconductor memory such as a USB memory and a memory card), and installing the program onto the general-purpose computer using the external memory device 262. The method of providing the program to the computer is not limited to the external memory device 262. The program may be directly provided to the computer by a communication means such as the receiver 285 and the network 263 (Internet and a dedicated line) instead of the external memory device 262. The memory device 260c and the external memory device 262 may be embodied by a computer-readable recording medium. Hereafter, the memory device 260c and the external memory device 262 are collectively referred to as recording media. In the present specification, “recording media” may refer to only the memory device 260c, only the external memory device 262, or both.

(2) Substrate Processing

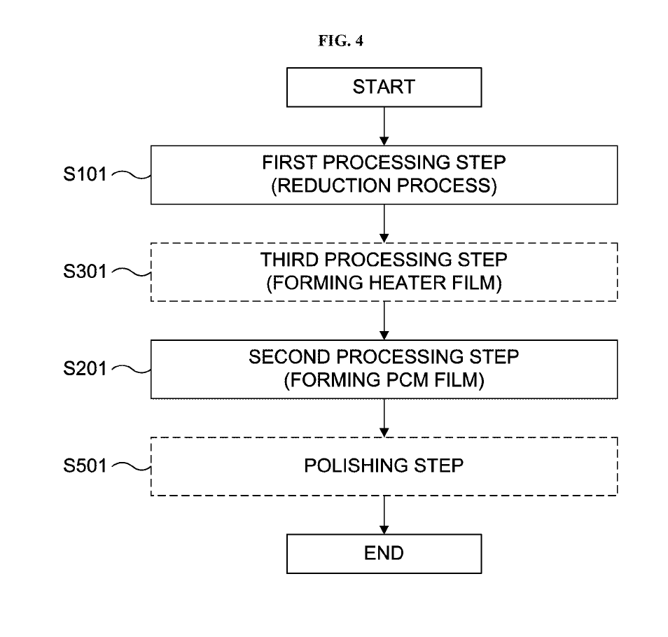

Hereinafter, the exemplary substrate processing sequence for forming a germanium antimony telluride (GeSbTe) film serving as the phase change film on the substrate 300 such as a wafer, which is one of steps for a method of manufacturing a semiconductor device, will be described with reference to FIGS. 4 through 14. In the present specification, the phase change film refers to a film whose electrical characteristics are changed by parameters such as voltage and current applied to the film, for example, a film whose resistance or crystal structure is changed.

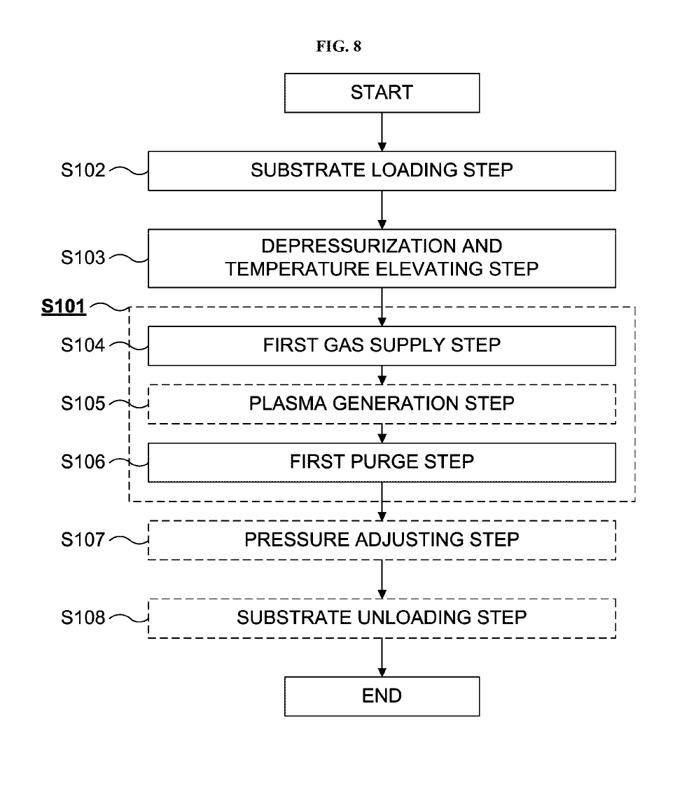

In the following description, the operation procedure of each apparatus is set by the process recipe (program) described above. The controller 260 controls the operation of each component constituting the substrate processing apparatus 100 according to the program. FIG. 4 is a flowchart illustrating a part of semiconductor manufacturing processes (the substrate processing). FIGS. 5A through 7D schematically illustrate cross-sectional views of the substrate for each manufacturing process. FIGS. 8 through 14 are flowcharts illustrating processing steps shown in FIG. 4 in detail.

As shown in FIG. 4, the substrate processing according to the embodiment includes the first processing step S101 and the second processing step S201. Preferably, the third processing step S301 indicated by a broken line is performed between the first processing step S101 and the second processing step S201. More preferably, a chemical mechanical polishing (CMP) step S501 indicated by a broken line is performed after the second processing step S201. Each step of the substrate processing will be described below in detail.

First, the substrate 300 on which the first processing step S101 is performed will be described. As shown in FIGS. SA, 6A and 7A, a conductive film 301 serving as a first metal-containing film and an insulating film 302 are formed on the substrate 300. In the present specification, the conductive film 301 is also referred to a metal-containing film. For example, the conductive film 301 refers to a metal-containing film such as a tungsten (W) film, a tungsten nitride (WN) film, a SeAsGe film and a SeAsGeSi film. The insulating film 302 refers to a film containing silicon (Si) element and oxygen (O) element. For example, the insulating film 302 may include a silicon oxide (SiO₂) film. The insulating film 302 may include a low-k film having a low dielectric constant. A patterning step (not shown) is performed on the substrate 300 shown in FIGS. 5A, 6A and 7A to form recesses 303 shown in FIGS. SB, 6B and 7B. The conductive film 301 is exposed at bottoms 303b of the recesses 303. According to the embodiment, by forming a phase change film 304 described later on the substrate 300 with the recesses 303 shown in FIGS. SB, 6B and 7B, it is possible to form a structure that the phase change film 304 and the insulating film 302 adjacent to the phase change film 304 are mutually supported. Therefore, it possible to suppress a pattern collapse of the phase change film 304 in the chemical mechanical polishing (CMP) step S501 performed after forming the phase change film 304. According to the conventional manufacturing processes of a semiconductor device, the phase change film 304 is directly formed on the conductive film 301 of a substrate that no insulating film 302 or no recess 303 is formed thereon, then, recesses 303 are formed by patterning the phase change film 304 and the insulating film 302 is formed on the recesses 303. According to conventional manufacturing processes, after forming the phase change film 304 or other films formed after the phase change film 304, the temperature (allowable temperature) that the substrate 300 can withstand decreases. Thus, it becomes difficult to apply a film-forming temperature for forming the phase change film 304 with good quality. Therefore, according to the conventional manufacturing processes, the characteristics of the insulating film 302 may deteriorate.

However, according to the embodiment, oxygen (O) is adsorbed on the conductive film 301 exposed on the bottoms 303b of the recesses 303 during the patterning step (not shown) of the insulating film 302 or a transfer step (not shown) preformed after the patterning step. Specifically, oxygen (O₂) gas present in the atmosphere during the transfer step or moisture (H₂O, OH) used in the patterning step is adsorbed on the conductive film 301. When the phase change film 304 is formed in the recesses 303 in the second processing step S201 described later while the oxygen is adsorbed on the conductive film 301, the characteristics of the phase change film 304 and the conductive film 301 may deteriorate. Specifically, the resistance of the conductive film 301 or the resistance of the interface between the phase change film 304 and the conductive film 301 increases. When the substrate 300 shown in FIGS. 5B, 6B and 7B is processed in the second process step S201, by differentiating the film-forming rate at the bottoms 303b of the recesses 303 and the film-forming rate at a top surface 302a of the insulating film 302, the phase change film 304 can be formed in the recesses 303 before the phase change film 304 is formed on the top surface 302a of the insulating film 302. That is, the phase change film 304 can be selectively deposited on the bottoms 303b of the recesses 303. However, when the oxygen is adsorbed on the bottoms 303b as described above, the film-forming rate at the bottoms 303b decreases and the phase change film 304 cannot be selectively deposited on the bottoms 303b. As a result, the time for performing the second processing step S201 is increased and the chemical mechanical polishing (CMP) step S501 performed after the processing process step S201 may not be properly adjusted. In the embodiment, “the time for performing the second processing step S201” refers to a time required for filling the recesses 303 with the phase change film 304.

Hereinafter, the substrate processing including the first processing step S101 by the substrate processing apparatus 100a will be described with reference to FIGS. 5B, 6B, 7B and 8.

<Substrate Loading Step S102>

First, the substrate 300 is loaded into the process chamber 201 of the substrate processing apparatus 100a. Specifically, the substrate support part 210 is lowered by the elevating mechanism 218, the lift pins 207 protrude from the upper surface of the substrate support part 210 through the holes 214. After the inner pressure of the process chamber 201 or the inner pressure of the transfer chamber 203 is adjusted to a predetermined pressure, the gate valve 1490 is opened. Then, the substrate 300 is transferred through the gate valve 1490 and placed on the lift pins 207. After the substrate 300 is placed on the lift pins 207, the gate valve 1490 is closed. By elevating the substrate support part 210 to a predetermined position by the elevating mechanism 218, the substrate 300 is transferred from the lift pins 207 to the substrate support part 210.

<Depressurization and Temperature Elevating Step S103>

Next, the process chamber 201 is exhausted through the exhaust pipe 224 until the inner pressure of the process chamber 201 reaches a predetermined level (vacuum level). In a depressurization and temperature elevating step S103, the opening degree of the pressure controller 227, which is an APC valve, is feedback-controlled based on the pressure measured by a pressure sensor (not shown). The amount of current applied to the heater 213 is feedback-controlled based on the temperature value detected by a temperature sensor (not shown) until the temperature of the substrate 300 reaches a predetermined temperature. Specifically, the substrate support part 210 is heated in advance by the heater 213 until the temperature of the substrate 300 or the temperature of the substrate support part 210 is stable. When gas from members or moisture is present in the process chamber 201, the gas or the moisture may be removed by vacuum-exhaust or purged with N₂ gas. The pre-processing step before the film-forming process is now complete. It is preferable that the process chamber 201 is exhausted to a vacuum level that can be reached by the vacuum pump 223 at once.

In the depressurization and temperature elevating step S103, the temperature of the heater 213 may range from 100° C. to 700° C., preferably from 200° C. to 400° C.

<First Processing Step S101>

Hereinafter, as the first processing step S101, an example of a reduction step for removing oxygen adsorbed to the bottoms 303b will be described.

<First Gas Supply Step S104>

In a first gas supply step S104, H₂ gas serving as the first gas is supplied onto the substrate 300 in the process chamber 201 of the substrate processing apparatus 100a. Specifically, the H₂ gas is supplied from the first gas supply source 113. The H₂ gas having the flow rate thereof adjusted by the MFC 115 is supplied to the substrate processing apparatus 100a. The H₂ gas having the flow rate thereof adjusted is then supplied to the depressurized process chamber 201 through the buffer chamber 232 and the holes 234a of the shower head 234. The exhaust system continuously exhausts the process chamber 201 such that the inner pressure of the process chamber 201 is maintained at a predetermined pressure. In the first gas supply step S104, the predetermined pressure may range from 10 Pa to 1000 Pa, for example. By supplying the H₂ gas to the substrate 300, the oxygen adsorbed on the bottoms 303b is removed (reduced).

<Plasma Generation Step S105>

A plasma generation step S105 as shown in FIG. 8 by a broken line may be performed. In the plasma generation step S105, at least one of the first high frequency power supply 252, the second high frequency power supply 352 and the RPU 114 may used to activate the H₂ gas supplied to the process chamber 201. When the first high frequency power supply 252 is used, the H₂ gas supplied into the process chamber 201 activated into a plasma state by supplying high frequency power from the first high frequency power supply 252 to the first electrode 244. When the second high frequency power supply 352 is used, the H₂ gas supplied into the process chamber 201 activated into a plasma state by supplying high frequency power from the second high frequency power supply 352 to the second electrode 256. When the first high frequency power supply 252 and the second high frequency power supply 352 are used in combination, preferably, the frequency of the electromagnetic wave (high frequency power) supplied from the second high frequency power supply 352 is lower than the frequency of the electromagnetic wave (high frequency power) supplied from the first high frequency power supply 252. By supplying the electromagnetic wave from the second high frequency power supply 352 having a frequency lower than that of the electromagnetic wave from the first high frequency power supply 252, it is possible to increase the amount of active hydrogen drawn into the substrate 300. That is, even if the aspect ratio of the recesses 303 becomes high with the development of the miniaturization technology in the future, it is possible to remove the oxygen adsorbed to the bottoms 303b. When the RPU 114 is used, the RPU 114 activates the H₂ gas in the first gas supply pipe 113a. When the RPU 114 is used, a part of active hydrogen generated in the first gas supply pipe 113a is deactivated at the shower head 234. Thus, the activation of the H₂ gas is performed softly when the RPU 114 is used as compared with the activation of the H₂ gas when the H₂ gas is directly activated in the process chamber 201.

Although the high frequency power is supplied after the first gas is supplied in FIG. 8, it is possible to supply the high frequency power before supplying the first gas and to generate the plasma when the first gas is supplied.

<First Purge Step S106>

After the oxygen adsorbed to the bottoms 303b of the recesses 303 is removed, the gas valve 116 at the first gas supply pipe 113a is closed to stop the supply of the H₂ gas. A first purge step S106 is performed by stopping the supply of the H₂ gas (first gas) and exhausting the first gas present in the process chamber 201 or the buffer chamber 232 by the exhaust system.

In the first purge step S106, the remaining gas may be extruded by further supplying the inert gas from the fifth gas supply mechanism in addition to exhausting the gas by the vacuum exhaust. When the inert gas is supplied, the valve 156 is opened and the flow rate of the inert gas is adjusted by the MFC 155. The vacuum exhaust may be combined with the supply of the inert gas. In the alternative, the vacuum exhaust and the supply of the inert gas may be alternatively performed.

After a predetermined time elapses, the supply of the inert gas is stopped by closing the valve 156. However, the inert gas may be continuously supplied by maintaining the valve 156 open.

For example, the flow rate of the N₂ gas serving as the inert gas supplied from the fifth gas supply mechanism may range from 100 sccm to 20,000 sccm.

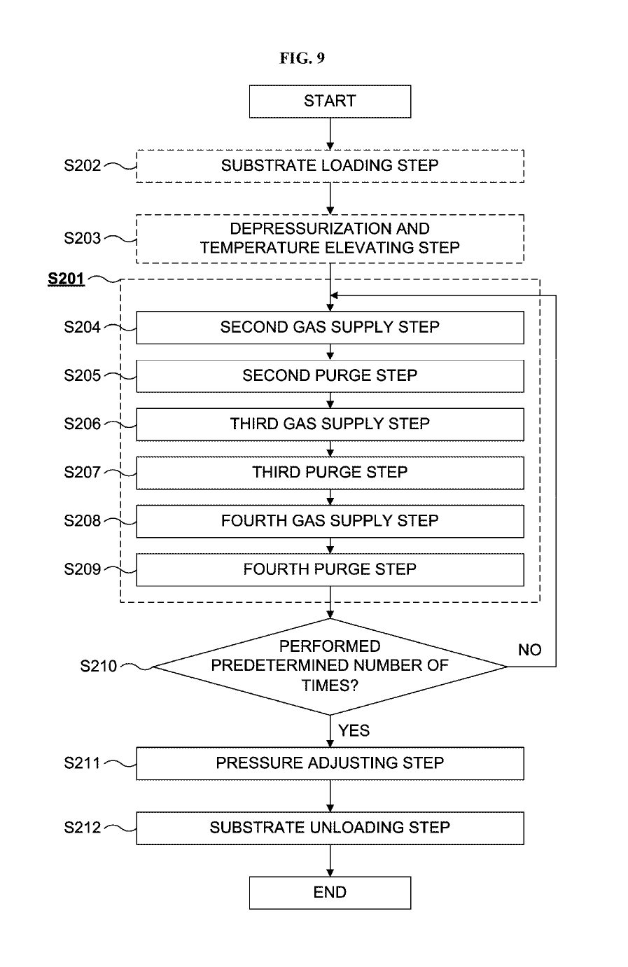

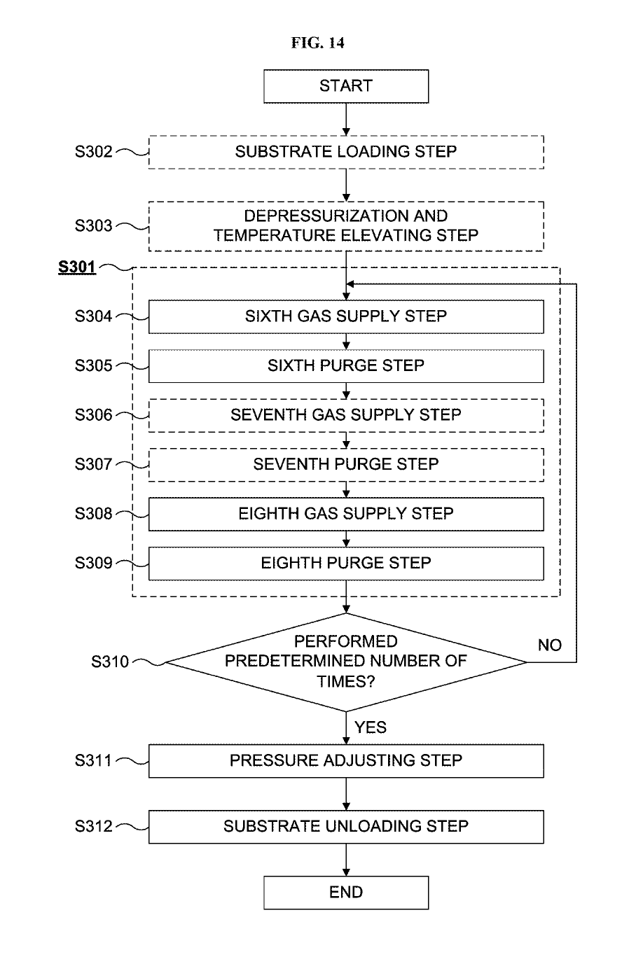

After the first purge step S106 is complete, a pressure adjusting step S107 and a substrate unloading step S108 are performed. Alternatively, the second processing step S201 shown in FIG. 9 or the third processing step S203 shown in FIG. 14 may be performed in the substrate processing apparatus 100a without unloading the substrate 300.

<Pressure Adjusting Step S107>

After the first purge step S106 is complete, the process chamber 201 or the transfer chamber 203 is exhausted through the first exhaust port 221 until the inner pressure of the process chamber 201 or the inner pressure of the transfer chamber 203 reaches a predetermined level (vacuum level) in the pressure adjusting step S107. Before, during or after the pressure adjusting step S107, the substrate 300 may be supported by the lift pins 207 until the substrate 300 is cooled down to a predetermined temperature.

<Substrate Unloading Step S108>

After the inner pressure of the process chamber 201 is adjusted to a predetermined pressure in the pressure adjusting step S107, the gate valve 1490 is opened. Then, the substrate 300 is unloaded from the transfer chamber 203 of the substrate processing apparatus 100a to the vacuum transfer chamber 2400.

Hereinafter, the substrate processing including the second processing step S201 of forming the phase change film 304 (e.g., phase change memory, PCM) in the recesses 303 of the substrate 300 shown in FIGS. 5B, 6B and 7B will be described with reference to FIG. 9. The second processing step S201 is performed by the substrate processing apparatus 100b. Alternatively, the second processing step S201 may be performed by the substrate processing apparatus 100a as described above.

<Substrate Loading Step S202>

First, the substrate 300 after the first processing step S101 is performed is loaded into the process chamber 201 of the substrate processing apparatus 100b. A substrate loading step S202 is substantially the same as the substrate loading step S102. Therefore, detailed descriptions of the substrate loading step S202 are omitted.

<Depressurization and Temperature Elevating Step S203>

Next, the process chamber 201 is exhausted through the exhaust pipe 224 until the inner pressure of the process chamber 201 reaches a predetermined level (vacuum level). A depressurization and temperature elevating step S203 is substantially the same as the depressurization and temperature elevating step S103. Therefore, detailed descriptions of the depressurization and temperature elevating step S203 are omitted.

<Second Processing Step S201>

Hereinafter, as the second processing step S201, an example of forming the phase change film 304 in the recesses 303 of the substrate 300 will be described.

<Second Gas Supply Step S204>

In a second gas supply step S204, TDMAGe gas serving as the second gas is supplied onto the substrate 300 in the process chamber 201 of the substrate processing apparatus 100b. Specifically, the TDMAGe gas is supplied from the second gas supply source 123. The TDMAGe gas having the flow rate thereof adjusted by the MFC 125 is supplied to the substrate processing apparatus 100b. The TDMAGe gas having the flow rate thereof adjusted is then supplied to the depressurized process chamber 201 through the buffer chamber 232 and the holes 234a of the shower head 234. The exhaust system continuously exhausts the process chamber 201 such that the inner pressure of the process chamber 201 is maintained at a predetermined pressure. In the second gas supply step S204, the predetermined pressure may range from 10 Pa to 1,000 Pa, for example. By supplying the TDMAGe gas to the substrate 300, a layer containing germanium (Ge) is deposited in the recesses 303.

<Second Purge Step S205>

Next, a second purge step S205 is performed. In the second purge step S205, the gas valve 126 at the second gas supply pipe 123a is closed to stop the supply of the TDMAGe gas. The second purge step S205 is performed by stopping the supply of the TDMAGe gas (second gas) and exhausting the second gas present in the process chamber 201 or the buffer chamber 232 by the exhaust system. Similar to the first purge step S106 described above, the inert gas may be supplied in the second purge step S205.

<Third Gas Supply Step S206>

Next, in a third gas supply step S206, TDMASb gas serving as the third gas is supplied onto the substrate 300 in the process chamber 201 of the substrate processing apparatus 100b. Specifically, the TDMASb gas is supplied from the third gas supply source 133. The TDMASb gas having the flow rate thereof adjusted by the MFC 135 is supplied to the substrate processing apparatus 100b. The TDMASb gas having the flow rate thereof adjusted is then supplied to the depressurized process chamber 201 and exhausted from the process chamber 201 in a manner similar to the above-described second gas supply step S204. In the third gas supply step S206, the predetermined pressure may range from 10 Pa to 1,000 Pa, for example. By supplying the TDMASb gas to the substrate 300, a layer containing antimony (Sb) is deposited on the layer containing germanium (Ge) in the recesses 303.

<Third Purge Step S207>

Next, a third purge step S207 is performed. In the third purge step S207, the gas valve 136 at the third gas supply pipe 133a is closed to stop the supply of the TDMASb gas. The third purge step S207 is performed by stopping the supply of the TDMASb gas (third gas) and exhausting the third gas present in the process chamber 201 or the buffer chamber 232 by the exhaust system. Similar to the first purge step S106 described above, the inert gas may be supplied in the third purge step S207.

<Fourth Gas Supply Step S208>

Next, in a fourth gas supply step S208, DtBTe gas serving as the fourth gas is supplied onto the substrate 300 in the process chamber 201 of the substrate processing apparatus 100b. Specifically, the DtBTe gas is supplied from the fourth gas supply source 143. The DtBTe gas having the flow rate thereof adjusted by the MFC 145 is supplied to the substrate processing apparatus 100b. The DtBTe gas having the flow rate thereof adjusted is then supplied to the depressurized process chamber 201 and exhausted from the process chamber 201 in a manner similar to the above-described second gas supply step S204. In the fourth gas supply step S208, the predetermined pressure may range from 10 Pa to 1,000 Pa, for example. By supplying the DtBTe gas to the substrate 300, a layer containing tellurium (Te) is deposited on the layer containing antimony (Sb) in the recesses 303. As a result, a layer containing germanium (Ge), antimony (Sb) and tellurium (Te) is deposited in the recesses 303.

<Fourth Purge Step S209>

Next, a fourth purge step S209 is performed. In the fourth purge step S209, the gas valve 146 at the fourth gas supply pipe 143a is closed to stop the supply of the DtBTe gas. The fourth purge step S209 is performed by stopping the supply of the DtBTe gas (fourth gas) and exhausting the fourth gas present in the process chamber 201 or the buffer chamber 232 by the exhaust system. Similar to the first purge step S106 described above, the inert gas may be supplied in the fourth purge step S209.

<Determination Step S210>

After the fourth purge step S209 is complete, the controller 260 determines whether the second processing step S201 (i.e., the step S204 through the step S209) is performed a predetermined number of times (n times). That is, the controller 260 determines whether a film containing germanium (Ge), antimony (Sb) and tellurium (Te) serving as the phase change film 304 is formed with a desired thickness to fill the recesses 303 of the substrate 300. The phase change film 304 having the desired thickness may be formed in the recesses 303 of the substrate 300 by performing a cycle including the step S204 through the step S209 at least once. It is preferable that the cycle is performed multiple times until the phase change film 304 having the desired thickness is formed. While the second gas is supplied first in the cycle, the embodiment is not limited thereto. For example, the third gas may be supplied first in the cycle. By supplying the third gas first in the cycle, it is possible to improve the adhesion of the phase change film 304 to the conductive film 301. Therefore, it is possible to prevent the phase change film 304 from being damaged in the CMP step S501 which is performed after forming the phase change film 304.

When the controller 260 determines, in the determination step S210, that the cycle is not performed the predetermined number of times (“NO” in FIG. 9), the second processing step S201 is repeated. When the controller 260 determines, in the determination step S210, that the cycle is performed the predetermined number of times (“YES” in FIG. 9), the second processing step S201 is terminated. Then, a pressure adjusting step S211 and a substrate unloading step S212 are performed. The pressure adjusting step S211 and the substrate unloading step S212 are substantially the same as the pressure adjusting step S107 and the substrate unloading step S108, respectively. Therefore, detailed descriptions of the pressure adjusting step S211 and the substrate unloading step S212 are omitted.

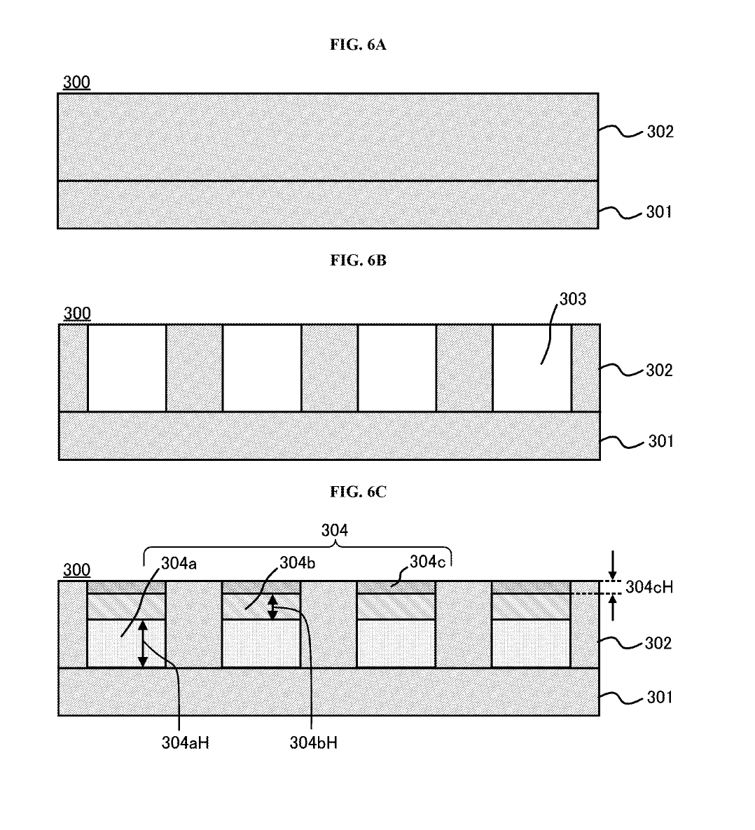

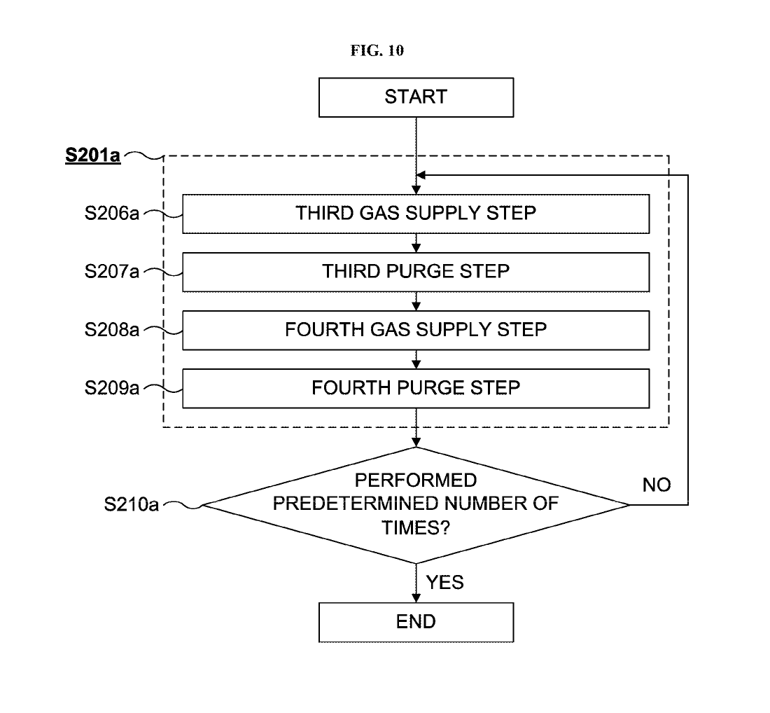

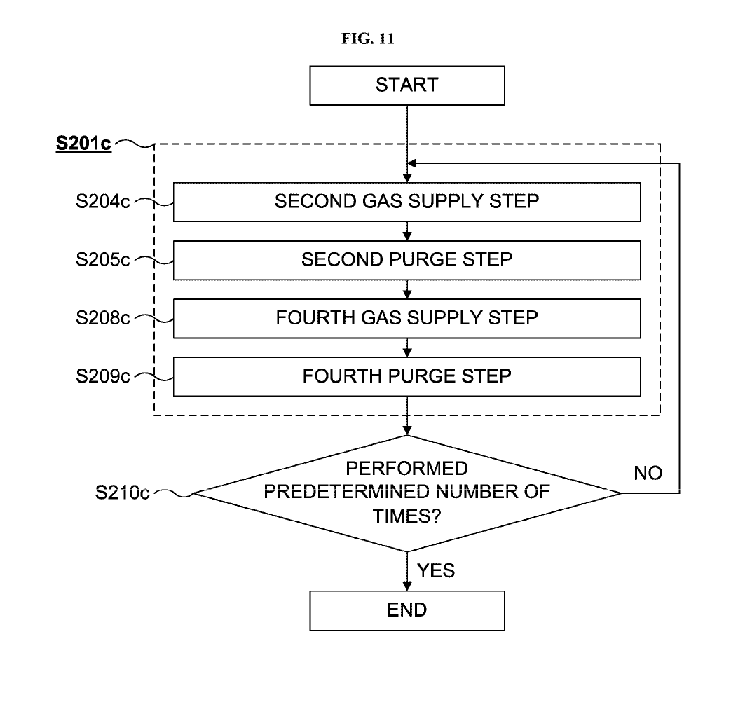

While the second processing step S201 of supplying the second gas, the third gas and the fourth gas sequentially is illustrated in FIG. 9, the embodiment is not limited thereto. For example, as shown in FIGS. 6C and 10, the phase change film 304 may be formed by stacking films 304a and 304b containing antimony (Sb) and tellurium (Te) and a film 304c containing germanium (Ge) and tellurium (Te). FIG. 10 is a flowchart illustrating a first modified example of the second processing step, that is, a processing step S201a of forming the films 304a and 304b containing antimony (Sb) and tellurium (Te). FIG. 11 is a flowchart illustrating a second modified example of the second processing step, that is, a processing step S201c of forming the film 304c containing germanium (Ge) and tellurium (Te).

As shown in FIG. 10, the processing step S201a includes a third gas supply step S206a, a third purge step S207a, a fourth gas supply step S208a, a fourth purge step S209a and a determination step S210a. The third gas supply step S206a, the third purge step S207a, the fourth gas supply step S208a, the fourth purge step S209a and the determination step S210a are substantially the same as the third gas supply step S206, the third purge step S207, the fourth gas supply step S208, the fourth purge step S209 and the determination step S210, respectively. Therefore, detailed descriptions of the third gas supply step S206a, the third purge step S207a, the fourth gas supply step S208a, the fourth purge step S209a and the determination step S210a are omitted. The films 304a and 304b containing antimony (Sb) and tellurium (Te) are, for example, films having different compositions. For example, the film 304a may be a Sb₂Te film and the film 304b may be Sb₂Te₃ film. The compositions of the films 304a and 304b is controlled by the flow rates and the time durations of the third gas and the fourth gas in the third gas supply step S206a and the fourth gas supply step S208a, respectively. Specifically, when increasing the ratio of antimony (Sb) in the films 304a and 304b, at least one of the flow rate and the time duration of the third gas is adjusted such that the flow rate of the third gas is greater than that of the fourth gas, or the time duration of the third gas is greater than that of the fourth gas, or both. The films 304a and 304b are formed such that a thickness 304aH of the film 304a is greater than a thickness 304bH of the film 304b, as shown in FIG. 6C. For example, the thickness 304aH is 10 nm and the thickness 304bH is 4 nm. By forming the films 304a and 304b containing antimony (Sb) and tellurium (Te) as above described, it is possible to improve the characteristics of the phase change film 304 and improve the selectivity of film-forming in the recesses 303. It is also possible to improve the adhesion between the phase change film 304 and the conductive film 301 thereunder. Therefore, it is possible to prevent the phase change film 304 from being damaged in the CMP step S501 which is performed after forming the phase change film 304. As a result, the characteristics of the semiconductor device can be improved.

As shown in FIG. 11, the processing step S201c includes a second gas supply step S204c, a second purge step S205c, a fourth gas supply step S208c, a fourth purge step S209c and a determination step S210c. The second gas supply step S204c, the second purge step S205c, the fourth gas supply step S208c, the fourth purge step S209c and the determination step S210c are substantially the same as the second gas supply step S204, the second purge step S205, the fourth gas supply step S208, the fourth purge step S209 and the determination step S210, respectively. Therefore, detailed descriptions of the second gas supply step S204c, the second purge step S205c, the fourth gas supply step S208c, the fourth purge step S209c and the determination step S210c are omitted. By alternately supplying the second gas and the fourth gas to form the film 304c containing germanium (Ge) and tellurium (Te), the phase change film 304 is formed as shown in FIG. 6C. The film 304c is formed such that a thickness 304cH of the film 304c is less than the thickness 304bH of the film 304b.

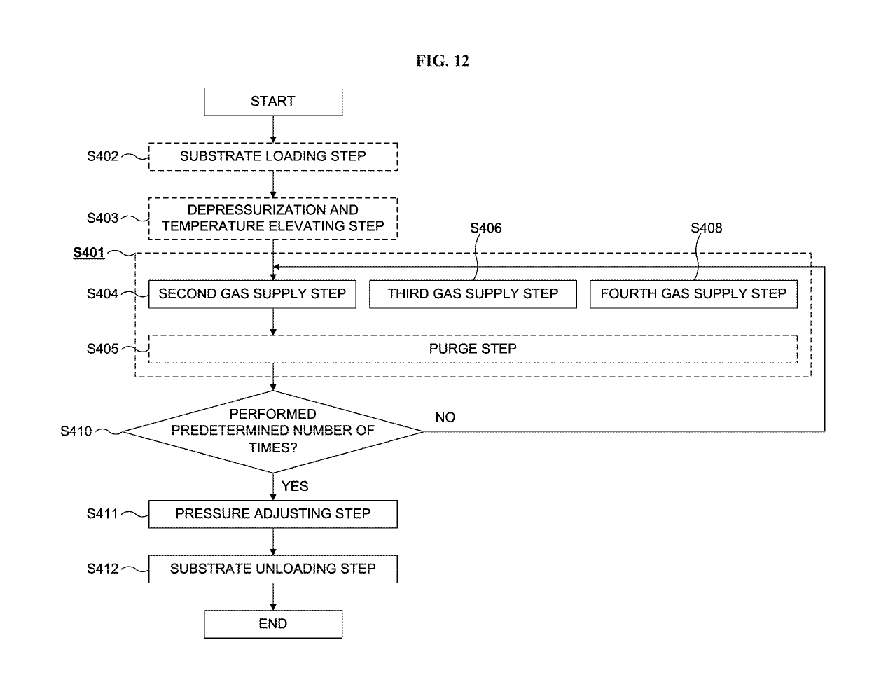

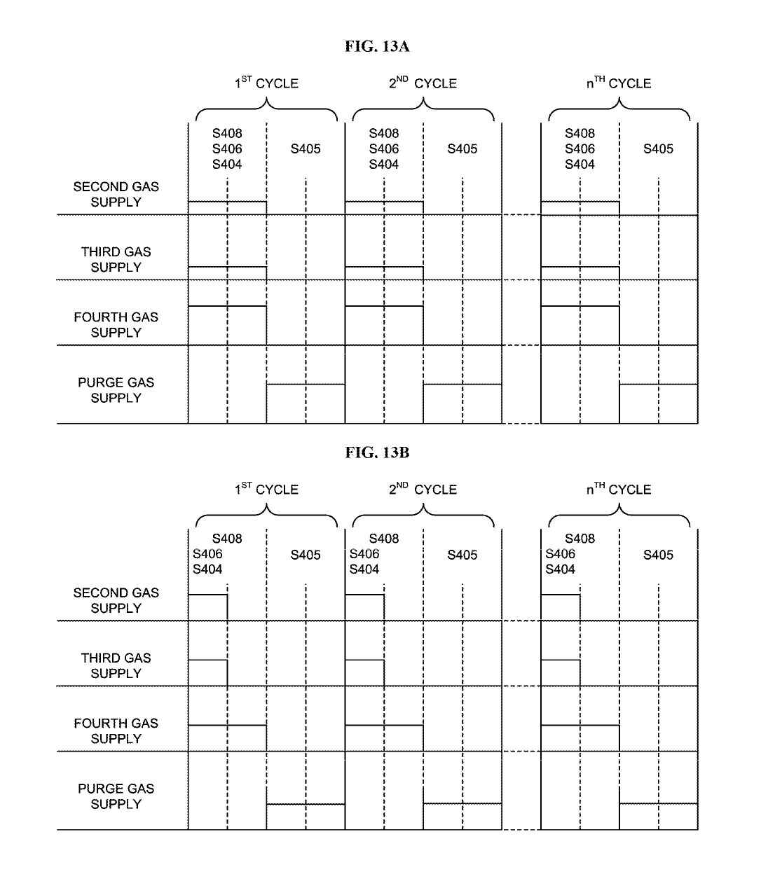

As describe above, while the film containing germanium (Ge), antimony (Sb) and tellurium (Te) serving as the phase change film 304 is formed by stacking layers such as the layer containing germanium (Ge), the layer containing antimony (Sb), the layer containing tellurium (Te), the layer containing antimony (Sb) and tellurium (Te) and the layer containing germanium (Ge) and tellurium (Te) according to the second processing step S201, the embodiment is not limited thereto. For example, a compound layer containing germanium (Ge), antimony (Sb) and tellurium (Te) is formed from the beginning to form the phase change film 304. A fourth processing step S401 of forming the compound layer will be described with reference to FIGS. 12, 13A and 13B. FIG. 12 is a flowchart illustrating the fourth processing step S401 and FIGS. 13A and 13B illustrate exemplary gas supply sequences of the fourth processing step S401.

As shown in FIG. 12, before or after the fourth processing step S401, a substrate loading step S402, a depressurization and temperature elevating step S403, a determination step S410, a pressure adjusting step S411 and a substrate unloading step S412 are performed, similarly to the second processing step S201 shown in FIG. 9. The substrate loading step S402, the depressurization and temperature elevating step S403, the determination step S410, the pressure adjusting step S411 and the substrate unloading step S412 are substantially the same as the substrate loading step S202, the depressurization and temperature elevating step S204, the determination step S210, the pressure adjusting step S211 and the substrate unloading step S212, respectively. Therefore, detailed descriptions of the substrate loading step S402, the depressurization and temperature elevating step S403, the determination step S410, the pressure adjusting step S411 and the substrate unloading step S412 are omitted.

Hereinafter, the fourth processing step S401 will be described in detail.

<Fourth Processing Step S401>

The fourth processing step S401 includes a second gas supply step S404, a third gas supply step S406, and a fourth gas supply step S408. As shown in FIGS. 13A and 13B, in these gas supply steps S404, S406 and S408, the second gas, the third gas and the fourth gas may supplied simultaneously only for a predetermined time. After these gas supply steps S404, S406 and S408 is complete, a purge step S405 substantially equal to the first purge step S106 may be performed.

The fourth processing step S401 will be described with reference to FIGS. 13A and 13B. Referring to FIG. 13A, the supply of the second gas, the third gas and the fourth gas are simultaneously started and simultaneously stopped. Referring to FIG. 13B, the supply of the second gas, the third gas and the fourth gas are simultaneously started, the supply of the second gas and the third gas is stopped after a predetermined time and the fourth gas may be supplied for another predetermined time. According to fourth processing step S401, the compound layer containing germanium (Ge), antimony (Sb) and tellurium (Te) is formed at once. The composition ratio of the compound layer may be adjusted based on adjusting the flow rates of the second gas, the third gas and the fourth gas supplied, as shown in FIG. 13A. The relative ratio of the flow rates of the second gas, the third gas and the fourth gas, for example, may be set to satisfy “the flow rate of the second gas:the flow rate of third gas:the flow rate of the fourth gas=1 to 3:1 to 3:4 to 6” to form the phase change film 304 having good characteristics. Preferably, the relative ratio of the flow rates of the second gas, the third gas and the fourth gas, for example, may be set to satisfy “the flow rate of the second gas:the flow rate of third gas:the flow rate of the fourth gas=2:2:5”. The relative composition ratio of the phase change film 304 having good characteristics may be set to satisfy “germanium:antimony:tellurium=1 to 3:1 to 3:4 to 6”, similar to the relative ratio of the flow rates of the second gas, the third gas and the fourth gas. Preferably, the relative composition ratio of the phase change film 304 having good characteristics, for example, may be set to satisfy “germanium:antimony:tellurium=2:2:5”. While the flow supplied to the process chamber 201 may be adjusted as shown in FIG. 13B. For example, while the flow rates of the second gas, the third gas and the fourth gas are substantially equal, the time durations of the second gas, the third gas and the fourth gas supplied to the process chamber 201 may be adjusted. The relative ratio of the time durations of the second gas, the third gas and the fourth gas supplied to the process chamber 201 may be the same as the relative ratio of the flow rates of the second gas, the third gas and the fourth gas.

By performing a one-time supply of the second gas, the third gas, and the fourth gas to form the phase change film 304, it is possible to improve the film-forming rate and to improve the manufacturing throughput of the semiconductor device.

Further, when the recesses 303 are deep, a cyclic process of the second gas supply step S404, the third gas supply step S406 and the fourth gas supply step S408 may be performed as shown in FIGS. 12, 13A and 13B. Specifically, a cycle including the gas supply step S404, the third gas supply step S406, the fourth gas supply step S408 and the purge step S405 is performed a predetermined number of times (at least twice). The gas supply steps S404, S406 and S408 and the purge step S405 are alternately performed. By performing the cyclic process, it is possible to uniformly form the phase change film 304 in the recesses 303 while suppressing the decrease in the film-forming rate in the recesses 303.

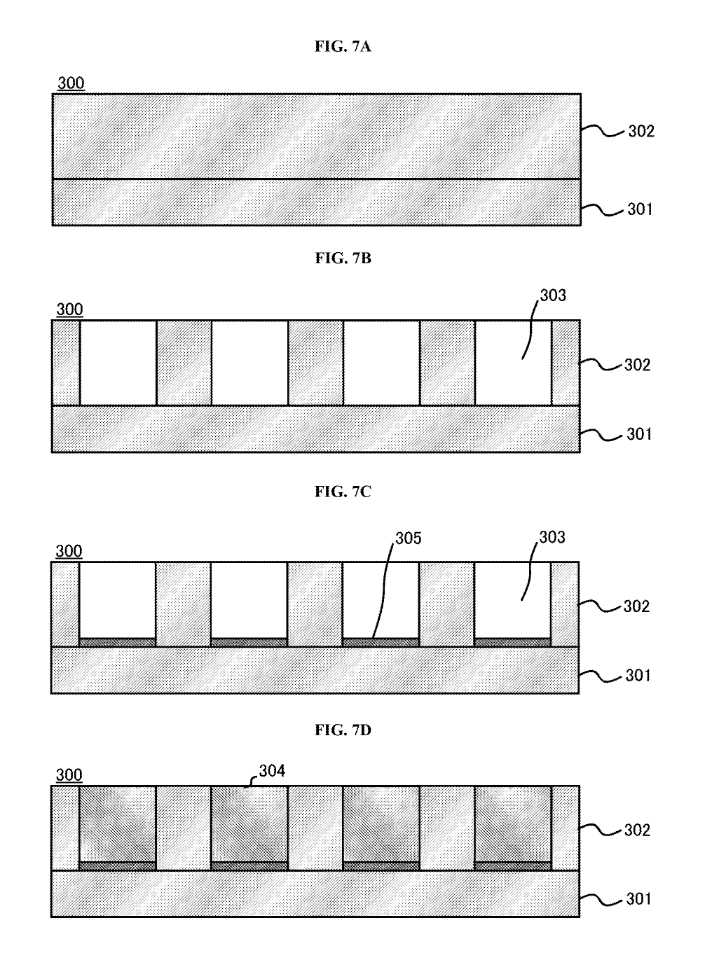

Hereinafter, the third processing step S301 performed between the first processing step S101 and the second processing step S201 will be described with reference to FIGS. 7 and 14. For example, a method of performing the substrate processing including the third processing step S301 by the substrate processing apparatus 100c will be described. In the third processing step S301, a titanium (Ti)-containing film serving as a second metal-containing film is formed on the conductive film 301 serving as the first metal-containing film. For example, the titanium-containing film is a film such as a titanium nitride (TiN) film and a titanium silicon nitride (TiSiN) film. The second metal-containing film acts as a heater film for heating the phase change film 304 in the semiconductor device. By heating the phase change film 304, it is possible to accelerate the change of the characteristics of the phase change film 304. That is, the characteristics of the semiconductor device can be improved.

<Substrate Loading Step S302>

First, the substrate 300 after the first processing step S101 is performed is loaded into the process chamber 201 of the substrate processing apparatus 100c. A substrate loading step S302 is substantially the same as the substrate loading step S102. Therefore, detailed descriptions of the substrate loading step S302 are omitted.

<Depressurization and Temperature Elevating Step S303>

Next, in a depressurization and temperature elevating step S303, the process chamber 201 is exhausted through the exhaust pipe 224 until the inner pressure of the process chamber 201 reaches a predetermined level (vacuum level), similarly to the depressurization and temperature elevating step S103 described above.

In the depressurization and temperature elevating step S303, the temperature of the heater 213 ranges from 100° C. to 600° C., preferably from 100° C. to 500° C., more preferably from 200° C. to 400° C.

<Third Processing Step 301>

Hereinafter, as the third processing step S301, an example of forming the titanium-containing film on the bottoms 303b of the recesses 303 will be described.

<Sixth Gas Supply Step S304>

Next, in a sixth gas supply step S304, TiCl₄ gas serving as the sixth gas is supplied onto the substrate 300 in the process chamber 201 of the substrate processing apparatus 100c. Specifically, the TiCl₄ gas is supplied from the sixth gas supply source 163. The TiCl₄ gas having the flow rate thereof adjusted by the MFC 165 is supplied to the substrate processing apparatus 100c. The TiCl₄ gas having the flow rate thereof adjusted is then supplied to the depressurized process chamber 201 through the buffer chamber 232 and the holes 234a of the shower head 234. The exhaust system continuously exhausts the process chamber 201 such that the inner pressure of the process chamber 201 is maintained at a predetermined pressure. In the sixth gas supply step $304, the predetermined pressure may range from 10 Pa to 1,000 Pa, for example. By supplying the TiCl₄ gas to the substrate 300, a titanium-containing layer is formed on the bottoms 303b of the recesses 303.

<Sixth Purge Step S305>

Next, a sixth purge step S305 is performed. In the sixth purge step S305, the gas valve 166 at the sixth gas supply pipe 163a is closed to stop the supply of the TiCl₄ gas. The sixth purge step S305 is performed by stopping the supply of the TiCl₄ gas (sixth gas) and exhausting the sixth gas present in the process chamber 201 or the buffer chamber 232 by the exhaust system. Similar to the first purge step S106 described above, the inert gas may be supplied in the sixth purge step S305.

<Seventh Gas Supply Step S306>

Next, in a seventh gas supply step S306, SiH₄ gas serving as the seventh gas is supplied onto the substrate 300 in the process chamber 201 of the substrate processing apparatus 100c. Specifically, the SiH₄ gas is supplied from the seventh gas supply source 173. The SiH₄ gas having the flow rate thereof adjusted by the MFC 175 is supplied to the substrate processing apparatus 100c. The SiH₄ gas having the flow rate thereof adjusted is then supplied to the depressurized process chamber 201 and exhausted from the process chamber 201 in a manner similar to the above-described sixth gas supply step S304. In the seventh gas supply step S306, the predetermined pressure may range from 10 Pa to 1,000 Pa, for example. By supplying the SiH₄ gas to the substrate 300, a layer containing silicon (Si) (also referred to as a “silicon-containing layer) is deposited on the titanium-containing layer in the recesses 303.

<Seventh Purge Step S307>

Next, a seventh purge step S307 is performed. In the seventh purge step S307, the gas valve 176 at the seventh gas supply pipe 173a is closed to stop the supply of the SiH₄ gas. The seventh purge step S307 is performed by stopping the supply of the SiH₄ gas (seventh gas) and exhausting the seventh gas present in the process chamber 201 or the buffer chamber 232 by the exhaust system. Similar to the first purge step S106 described above, the inert gas may be supplied in the seventh purge step S307.

<Eighth Gas Supply Step S308>

Next, in an eighth gas supply step S308, NH₃ gas serving as the eighth gas is supplied onto the substrate 300 in the process chamber 201 of the substrate processing apparatus 100c. Specifically, the NH₃ gas is supplied from the eighth gas supply source 183. The NH₃ gas having the flow rate thereof adjusted by the MFC 185 is supplied to the substrate processing apparatus 100c. The NH₃ gas having the flow rate thereof adjusted is then supplied to the depressurized process chamber 201 and exhausted from the process chamber 201 in a manner similar to the above-described sixth gas supply step S304. In the eighth gas supply step S308, the predetermined pressure may range from 10 Pa to 1,000 Pa, for example. By supplying the NH₃ gas to the substrate 300, a film containing titanium (Ti), silicon (Si) and nitrogen (N) (also referred to as a “TiSiN film”) by removing chlorine (Cl) contained in the titanium-containing layer and the silicon-containing layer in the recesses 303 and supplying nitrogen (N) to the titanium-containing layer and the silicon-containing layer.

<Eighth Purge Step S309>

Next, an eighth purge step S309 is performed. In the eighth purge step S309, the gas valve 186 at the eighth gas supply pipe 183a is closed to stop the supply of the NH₃ gas. The eighth purge step S309 is performed by stopping the supply of the NH₃ gas (eighth gas) and exhausting the eighth gas present in the process chamber 201 or the buffer chamber 232 by the exhaust system. Similar to the first purge step S106 described above, the inert gas may be supplied in the eighth purge step S309.

<Determination Step S310>

After the eighth purge step S309 is complete, the controller 260 determines whether the third processing step S301 (i.e., the step S304 through the step S309) is performed a predetermined number of times (n times). That is, the controller 260 determines whether a TiSiN film having a desired thickness is formed in the recesses 303 of the substrate 300. The TiSiN film 305 having the desired thickness shown in FIG. 7C may be formed in the recesses 303 of the substrate 300 by performing a cycle including the step S304 through the step S309 at least once. It is preferable that the cycle is performed multiple times until the TiSiN film having the desired thickness is formed.

When the controller 260 determines, in the determination step S310 that the cycle is not performed the predetermined number of times (“NO” in FIG. 14), the third processing step S301 is repeated. When the controller 260 determines, in the determination step S310, that the cycle is performed the predetermined number of times (“YES” in FIG. 14), the third processing step S301 is terminated. Then, a pressure adjusting step S311 and a substrate unloading step S312 are performed.

<Pressure Adjusting Step S311>

In the pressure adjusting step S311, the inner pressure of the process chamber 201 or the inner pressure of the transfer chamber 203 is adjusted in the same manner as the pressure adjusting step S107 described above.

<Substrate Unloading Step S312>

In the substrate unloading step S311, the substrate 300 is unloaded from the transfer chamber 203 in the same manner as the substrate unloading step S109 described above. After the substrate unloading step S311 is complete, the substrate processing including the second processing step S201 shown in FIG. 9 is performed to form the phase change film 304 on the TiSiN film 305, as shown in FIG. 7D.

<Polishing Step S501>

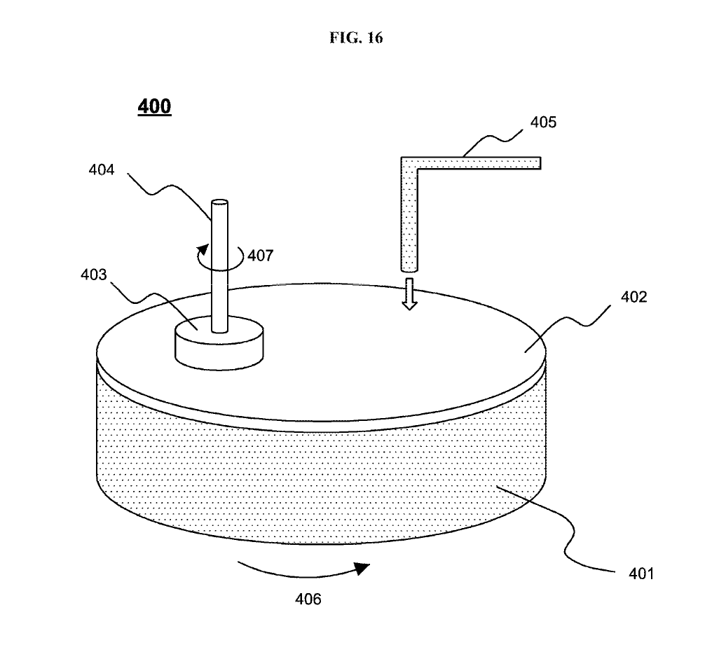

Next, the polishing step S501 performed after the second processing step S201 will be described with reference to FIGS. 4, 5D and 16. After the second process step S201 is performed, as shown in FIG. 5D which is an enlarged view of a broken line portion of FIG. 5C, a thin excess phase change film 304d may be formed on the top surface 302a of the insulating film 302. The excess phase change film 304d is removed in the polishing step S501. The polishing step S501 is performed by a polishing apparatus 400 shown in FIG. 16. In FIG. 16, a reference numeral 401 denotes a polishing board, and a reference numeral 402 denotes polishing cloth for polishing the substrate 300. The polishing board 401 is connected to a rotating mechanism (not shown), and rotated along the direction of an arrow 406 when polishing the substrate 300. The thickness of the excess phase change film 304d is smaller when the first processing step S101 is performed than when the first processing step S01 is not performed. As a result, the time required for polishing the substrate 300 can be shortened. It is also possible to prevent portions of the phase change film 304 whereon the excess phase change film 304d is not formed from being damaged in the polishing step S501.

A reference numeral 403 denotes a polishing head, and a shaft 404 is connected to an upper surface of the polishing head 403. The shaft 404 is connected to the rotating mechanism (not shown) and a vertical driving mechanism (not shown). While the substrate 300 is polished, the shaft 404 is rotated along the direction of an arrow 407.

A reference numeral 405 denotes a supply pipe for supplying slurry (polishing agent). While the substrate 300 is polished, the slurry is supplied toward the polishing cloth 402 via the supply pipe 405. In the polishing step S501, for example, an alkaline polishing agent is supplied. By using the alkaline polishing agent, it is possible to remove the excess phase change film 304d without damaging (oxidizing) the phase change film 304 and the insulating film 302. When an acidic polishing agent is used, the surface of the phase change film 304 may be oxidized, the electric characteristics of the phase change film 304 may deteriorate, and the contact characteristics between the phase change film 304 and the film formed thereon may be changed. By using the alkaline polishing agent according to the embodiment, it is possible to polish the substrate 300 (i.e., the excess phase change film 304d) without oxidizing the surface of the phase change film 304.

### Other Embodiments

While the technique is described in detail by way of the above-described embodiment, the above-described technique is not limited thereto. The above-described technique may be modified in various ways without departing from the gist thereof.

While a method of forming a film wherein a plurality of gases is sequentially supplied or alternately supplied (i.e., in a non-overlapping manner) is exemplified above, the above-described technique is not limited thereto. The above-described technique may be applied to other methods of forming a film. For example, the above-described technique may be applied to a case where the supply timings (durations) of the plurality of gases partially overlap. Specifically, the above-described technique may be applied to a CVD (Chemical Vapor Deposition) method, a cyclic CVD method and a sputtering using an antimony (Sb)-tellurium (Te) target or germanium (Ge)-tellurium (Te) target. It is possible to improve the film-forming rate of each film and to shorten the manufacturing throughput of the semiconductor device when the CVD, the cyclic CVD or the sputtering is used.

While a substrate processing apparatus capable of processing one substrate in one process chamber is exemplified above, the above-described technique is not limited thereto. The above-described technique may be applied to other substrate processing apparatuses. For example, the above-described technique may also be applied to a substrate processing apparatus capable of processing a plurality of substrates arranged horizontally or vertically.

According to the technique described herein, the quality of the phase change film formed on the substrate can be improved.

What is claimed is:

1. A method of manufacturing a semiconductor device, comprising:
(a) supplying a reducing first gas onto a substrate while heating the substrate, wherein the substrate includes a first metal-containing film and an insulating film with recesses and the first metal-containing film is exposed at the recesses; and
(b) supplying a second gas, a third gas and a fourth gas into the recesses to form a phase change film in the recesses after (a) is performed.

2. The method of claim 1, further comprising:
(c) forming a second metal-containing film on the first metal-containing film between (a) and (b).

3. The method of claim 1, wherein (a) comprises activating the first gas with two electric powers of different frequencies.

4. The method of claim 2, wherein (a) includes activating the first gas with two electric powers of different frequencies.

5. The method of claim 1, further comprising:
(d) supplying an alkaline polishing agent to the substrate to polish the substrate after (b) is performed.

6. The method of claim 2, further comprising:
(d) supplying an alkaline polishing agent to the substrate to polish the substrate after (b) is performed.

7. The method of claim 3, further comprising:
(d) supplying an alkaline polishing agent to the substrate to polish the substrate after (b) is performed.

8. The method of claim 4, further comprising:
(d) supplying an alkaline polishing agent to the substrate to polish the substrate after (b) is performed.
